(19) United States
(12) Patent Application Publication
(10) Pub. No.: US 2026/0358438 A1
(43) Pub. Date: Nov. 12, 2026

(54) POWER CABLE REMOVAL DETECTION

(71) Applicant: Meta Platforms Technologies, LLC, Menlo Park, CA (US)

(72) Inventors: Deepak Gopi, Milpitas, CA (US); Puneet Gupta, Milpitas, CA (US); Yiwen Wu, Oakland, CA (US)

(21) Appl. No.: 19/648,978

(22) Filed: Apr. 15, 2026

Related U.S. Application Data
(60) Provisional application No. 63/801,612, filed on May 7, 2025.

(51) Int. Cl. G01R 31/69; G06F 3/02

(52) U.S. Cl. CPC G01R 31/69; G06F 3/02

(57) ABSTRACT

An embodiment includes generating a cable removal detection signal event, the cable removal detection signal event generated upon detection of removal of a power cable connecting a head-worn mixed reality device to an external compute/battery device. An embodiment includes removing, responsive to generating the cable removal detection signal event, power from at least one of the head-worn mixed reality device and the external compute/battery device.

### CROSS-REFERENCE OF RELATED APPLICATION

This application claims the benefit of U.S. Provisional Application No. 63/801612, filed on May 7, 2025, which is incorporated herein in its entirety.

### TECHNICAL FIELD

The present disclosure generally relates to modular computing devices, and more particularly to power cable removal detection.

### BACKGROUND

The term “mixed reality” or “MR” as used herein refers to a form of reality that has been adjusted in some manner before presentation to a user, which may include, e.g., virtual reality (VR), augmented reality (AR), extended reality (XR), hybrid reality, or some combination and/or derivatives thereof. Mixed reality content may include completely generated content or generated content combined with captured content (e.g., real-world photographs). The mixed reality content may include video, audio, haptic feedback, or some combination thereof, any of which may be presented in a single channel or in multiple channels (such as stereo video that produces a three-dimensional (3D) effect to the viewer). Additionally, in some embodiments, mixed reality may be associated with applications, products, accessories, services, or some combination thereof, that are, e.g., used to interact with content in an immersive application. The mixed reality system that provides the mixed reality content may be implemented on various platforms, including a head-mounted display (HMD) connected to a server, a host computer system, a standalone HMD, a mobile device or computing system, a “cave” environment or other projection system, or any other hardware platform capable of providing mixed reality content to one or more viewers. Mixed reality may be equivalently referred to herein as “artificial reality.”

“Virtual reality” or “VR,” as used herein, refers to an immersive experience where a user’s visual input is controlled by a computing system. “Augmented reality” or “AR” as used herein refers to systems where a user views images of the real world after they have passed through a computing system. For example, a tablet with a camera on the back can capture images of the real world and then display the images on the screen on the opposite side of the tablet from the camera. The tablet can process and adjust or “augment” the images as they pass through the system, such as by adding virtual objects. AR also refers to systems where light entering a user’s eye is partially generated by a computing system and partially composes light reflected off objects in the real world. For example, an AR headset could be shaped as a pair of glasses with a pass-through display, which allows light from the real world to pass through a waveguide that simultaneously emits light from a projector in the AR headset, allowing the AR headset to present virtual objects intermixed with the real objects the user can see. The AR headset may be a block-light headset with video pass-through. “Mixed reality” or “MR,” as used herein, refers to any of VR, AR, XR, or any combination or hybrid thereof.

### SUMMARY

Some embodiments of the present disclosure provide a computer-implemented method for power cable removal detection. The method includes generating a cable removal detection signal event, the cable removal detection signal event generated upon detection of removal of a power cable connecting a head-worn mixed reality device to an external compute/battery device; and removing, responsive to generating the cable removal detection signal event, power from at least one of the head-worn mixed reality device and the external compute/battery device.

Some embodiments of the present disclosure provide a non-transitory computer-readable medium storing a program for power cable removal detection. The program, when executed by a computer, configures the computer to generate a cable removal detection signal event, the cable removal detection signal event generated upon detection of removal of a power cable connecting a head-worn mixed reality device to an external compute/battery device; and remove, responsive to generating the cable removal detection signal event, power from at least one of the head-worn mixed reality device and the external compute/battery device.

Some embodiments of the present disclosure provide a system for power cable removal detection. The system comprises a processor and a non-transitory computer readable medium storing a set of instructions, which when executed by the processor, configure the processor to generate a cable removal detection signal event, the cable removal detection signal event generated upon detection of removal of a power cable connecting a head-worn mixed reality device to an external compute/battery device; and remove, responsive to generating the cable removal detection signal event, power from at least one of the head-worn mixed reality device and the external compute/battery device.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments.

FIG. 1 illustrates a network architecture used to implement power cable removal detection, according to some embodiments.

FIG. 2 is a block diagram illustrating details of a system for power cable removal detection, according to some embodiments.

FIG. 3 depicts a block diagram of an example configuration for power cable removal detection, in accordance with an illustrative embodiment.

FIG. 4 depicts an example mechanical configuration for power cable removal detection, in accordance with an illustrative embodiment.

FIG. 5 depicts another example mechanical configuration for power cable removal detection, in accordance with an illustrative embodiment.

FIG. 6 depicts another example mechanical configuration for power cable removal detection. in accordance with an illustrative embodiment.

FIG. 7 depicts another example mechanical configuration for power cable removal detection. in accordance with an illustrative embodiment.

FIG. 8 depicts example events in power cable removal detection. in accordance with an illustrative embodiment.

FIG. 9 depicts example events in power cable removal detection. in accordance with an illustrative embodiment.

FIG. 10 depicts a flowchart of an example process for [title]. in accordance with an illustrative embodiment.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure.

In one MR architecture a head-worn MR device can be connected to an external compute/battery device using a removable cable to connect the two devices. The cable is removable at one or both devices. If the cable carries electrical power between the devices, there is a need for the head-worn and compute/battery devices to detect when the cable is disconnected (at either side or both sides) to avoid damaging a device from the sudden removal of power by triggering a graceful or safe power down upon cable removal.

Embodiments of the present disclosure address the above identified problems by implementing power cable removal detection.

Some embodiments implement power cable removal detection using a mechanical switch. A spring-loaded plunger (actuated by a button or self-actuated) presses on the mechanical switch when a cable plug is engaged. The mechanical switch is unpressed, or released, when the cable plug is removed. One embodiment includes a button mechanically coupled to the plunger. When a user presses the button, the plunger disengages and the mechanical switch is unpressed. In another embodiment, the plunger is designed to disengage as a user pulls the cable plug out, releasing the mechanical switch.

Some embodiments implement power cable removal detection using a Hall effect, or Hall, sensor in a device and a magnet in the power cable. The Hall sensor detects magnetic strength from the magnet in the cable, and the strength drops as the cable is removed.

Some embodiments implement power cable removal detection using a pressure sensor or strain gauge. A spring-loaded plunger (actuated by a button or self-actuated) applies pressure on a pressure sensor or strain gauge when a cable plug is engaged. The pressure is removed when the cable plug is removed. One embodiment includes a button mechanically coupled to the plunger. When a user presses the button, the plunger disengages and the pressure is removed from the pressure sensor or strain gauge. In another embodiment, the plunger is designed to disengage as a user pulls the cable plug out, removing pressure from the pressure sensor or strain gauge. Cable removal detection using a pressure sensor or strain gauge can take longer than using a mechanical switch or Hall sensor, but pressure fluctuations or decreases as the user tries to disengage the cable can provide early warning of the cable’s removal, increasing the time available to perform a graceful shutdown.

Some embodiments implement power cable removal detection using one or more capacitive sensors implemented in capacitive touch surfaces, arranged on the cable so that a user touches one or more of the capacitive touch surfaces on the cable when the user grasps the cable to remove it. One embodiment includes capacitive touch surfaces on two sides of the cable to minimize the risk of false triggering.

In an embodiment within a head-worn device, a cable removal detection signal event hits a microcontroller configured to detect cable removal. In another embodiment, a cable removal detection signal is routed to a power management circuit directly, bypassing the microcontroller). In response, the microcontroller signals the power management circuit to initiate a graceful shutdown of all the power rails on the head-worn device. In some embodiments, a power bank or battery temporarily supplies power for the scenario when power through the cable connector is shut off immediately, before the graceful shutdown completes. Another embodiment performs an additional task upon cable removal detection.

In an embodiment within a compute/battery device, a cable removal detection signal event hits a microcontroller or system-on-chip (SoC) configured to detect cable removal. In another embodiment, a cable removal detection signal is routed to a power management circuit directly, bypassing the microcontroller or SoC). In response, the microcontroller or SoC signals the power management circuit to initiate a graceful shutdown of all the power rails on the head-worn device. Another embodiment performs an additional task upon cable removal detection.

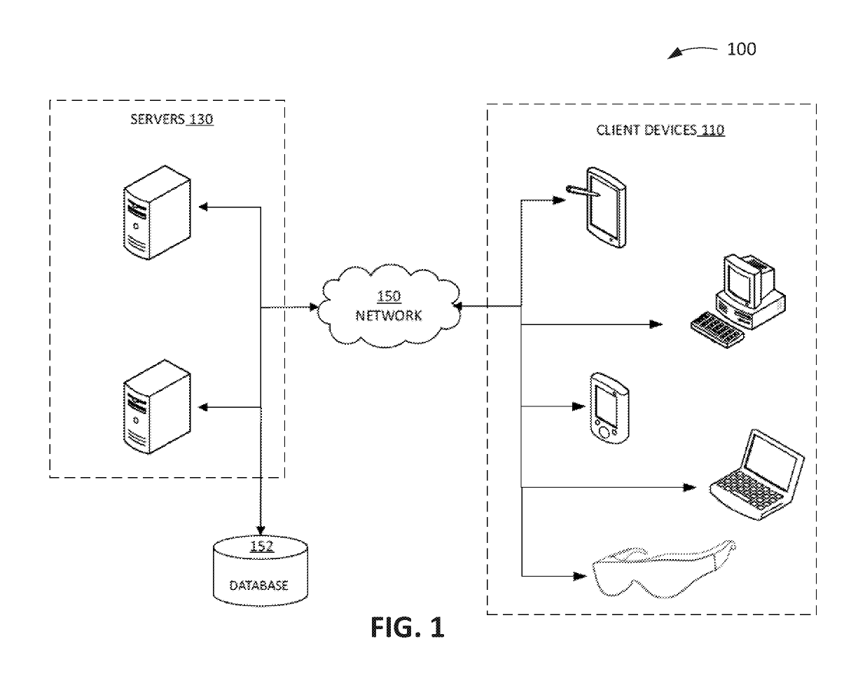

FIG. 1 illustrates a network architecture 100 used to implement power cable removal detection, according to some embodiments. The network architecture 100 may include one or more client devices 110 and servers 130, communicatively coupled via a network 150 with each other and to at least one database 152. Database 152 may store data and files associated with the servers 130 and/or the client devices 110. In some embodiments, client devices 110 collect data, video, images, and the like, for upload to the servers 130 to store in the database 152.

The network 150 may include a wired network (e.g., fiber optics, copper wire, telephone lines, and the like) and/or a wireless network (e.g., a satellite network, a cellular network, a radiofrequency (RF) network, Wi-Fi, Bluetooth, and the like). The network 150 may further include one or more of a local area network (LAN), a wide area network (WAN), the Internet, and the like. Further, the network 150 may include, but is not limited to, any one or more of the following network topologies, including a bus network, a star network, a ring network, a mesh network, and the like.

Client devices 110 may include, but are not limited to, laptop computers, desktop computers, and mobile devices such as smart phones, tablets, televisions, wearable devices, head-mounted devices, display devices, and the like.

In some embodiments, the servers 130 may be a cloud server or a group of cloud servers. In other embodiments, some or all of the servers 130 may not be cloud-based servers (i.e., may be implemented outside of a cloud computing environment, including but not limited to an on-premises environment), or may be partially cloud-based. Some or all of the servers 130 may be part of a cloud computing server, including but not limited to rack-mounted computing devices and panels. Such panels may include but are not limited to processing boards, switchboards, routers, and other network devices. In some embodiments, the servers 130 may include the client devices 110 as well, such that they are peers.

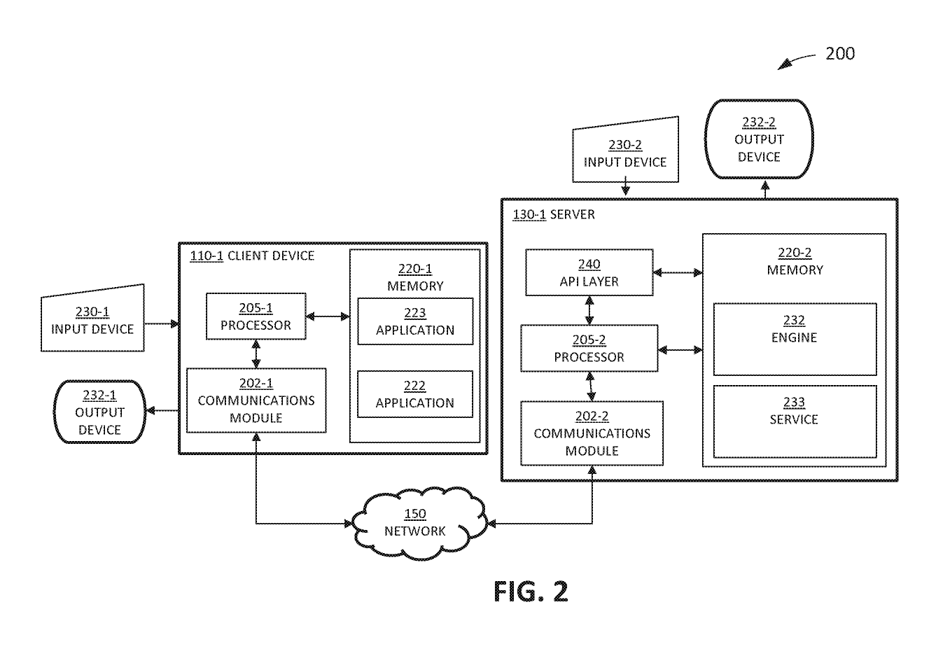

FIG. 2 is a block diagram illustrating details of a system 200 for power cable removal detection, according to some embodiments. Specifically, the example of FIG. 2 illustrates an exemplary client device 110-1 (of the client devices 110) and an exemplary server 130-1 (of the servers 130) in the network architecture 100 of FIG. 1.

Client device 110-1 and server 130-1 are communicatively coupled over network 150 via respective communications modules 202-1 and 202-2 (hereinafter, collectively referred to as “communications modules 202”). Communications modules 202 are configured to interface with network 150 to send and receive information, such as requests, data, messages, commands, and the like, to other devices on the network 150. Communications modules 202 can be, for example, modems or Ethernet cards, and/or may include radio hardware and software for wireless communications (e.g., via electromagnetic radiation, such as radiofrequency (RF), near field communications (NFC), Wi-Fi, and Bluetooth radio technology).

The client device 110-1 and server 130-1 also include a processor 205-1, 205-2 and memory 220-1, 220-2, respectively. Processors 205-1 and 205-2, and memories 220-1 and 220-2 will be collectively referred to, hereinafter, as “processors 205,” and “memories 220.” Processors 205 may be configured to execute instructions stored in memories 220, to cause client device 110-1 and/or server 130-1 to perform methods and operations consistent with embodiments of the present disclosure.

The client device 110-1 and the server 130-1 are each coupled to at least one input device 230-1 and input device 230-2, respectively (hereinafter, collectively referred to as “input devices 230”). The input devices 230 can include a mouse, a controller, a keyboard, a pointer, a stylus, a touchscreen, a microphone, voice recognition software, a joystick, a virtual joystick, a touch-screen display, and the like. In some embodiments, the input devices 230 may include cameras, microphones, sensors, and the like. In some embodiments, the sensors may include touch sensors, acoustic sensors, inertial motion units and the like.

The client device 110-1 and the server 130-1 are also coupled to at least one output device 232-1 and output device 232-2, respectively (hereinafter, collectively referred to as “output devices 232”). The output devices 232 may include a screen, a display (e.g., a same touchscreen display used as an input device), a speaker, an alarm, and the like. A user may interact with client device 110-1 and/or server 130-1 via the input devices 230 and the output devices 232.

Memory 220-1 may further include an application 222, configured to execute on client device 110-1 and couple with input device 230-1 and output device 232-1, and implement power cable removal detection. The application 222 may be downloaded by the user from server 130-1, and/or may be hosted by server 130-1. The application 222 may include specific instructions which, when executed by processor 205-1, cause operations to be performed consistent with embodiments of the present disclosure. In some embodiments, the application 222 runs on an operating system (OS) installed in client device 110-1. In some embodiments, application 222 may run within a web browser. In some embodiments, the processor 205-1 is configured to control a graphical user interface (GUI) (e.g., spanning at least a portion of input devices 230 and output devices 232) for the user of client device 110-1 to access the server 130-1.

In some embodiments, memory 220-2 includes an application engine 232. The application engine 232 may be configured to perform methods and operations consistent with embodiments of the present disclosure. The application engine 232 may share or provide features and resources with the client device 110-1, including data, libraries, and/or applications retrieved with application engine 232 (e.g., application 222). The user may access the application engine 232 through the application 222. The application 222 may be installed in client device 110-1 by the application engine 232 and/or may execute scripts, routines, programs, applications, and the like provided by the application engine 232.

Memory 220-1 may further include an application 223, configured to execute in client device 110-1. The application 223 may communicate with service 233 in memory 220-2 to provide power cable removal detection. The application 223 may communicate with service 233 through API layer 240, for example.

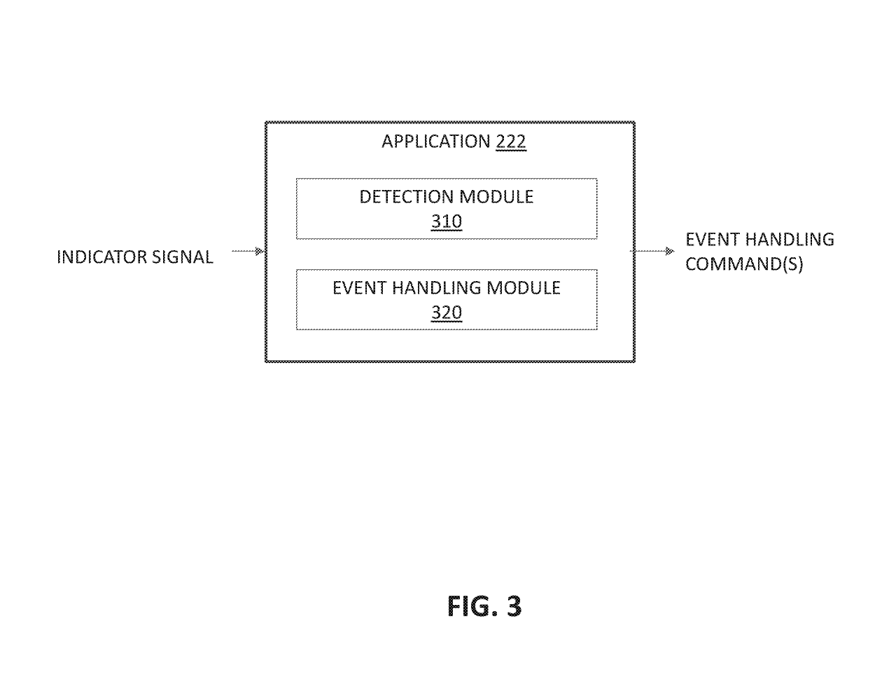

FIG. 3 depicts a block diagram of an example configuration for power cable removal detection, in accordance with an illustrative embodiment. Application 222 is the same as application 222 in FIG. 2.

Some implementations of detection module 310 implement power cable removal detection using a mechanical switch. A spring-loaded plunger (actuated by a button or self-actuated) presses on the mechanical switch when a cable plug is engaged. The mechanical switch is unpressed, or released, when the cable plug is removed. One embodiment includes a button mechanically coupled to the plunger. When a user presses the button, the plunger disengages and the mechanical switch is unpressed. In another embodiment, the plunger is designed to disengage as a user pulls the cable plug out, releasing the mechanical switch.

Some implementations of detection module 310 implement power cable removal detection using a Hall effect, or Hall, sensor in a device and a magnet in the power cable. The Hall sensor detects magnetic strength from the magnet in the cable, and the strength drops as the cable is removed.

Some implementations of detection module 310 implement power cable removal detection using a pressure sensor or strain gauge. A spring-loaded plunger (actuated by a button or self-actuated) applies pressure on a pressure sensor or strain gauge when a cable plug is engaged. The pressure is removed when the cable plug is removed. One embodiment includes a button mechanically coupled to the plunger. When a user presses the button, the plunger disengages and the pressure is removed from the pressure sensor or strain gauge. In another embodiment, the plunger is designed to disengage as a user pulls the cable plug out, removing pressure from the pressure sensor or strain gauge. Cable removal detection using a pressure sensor or strain gauge can take longer than using a mechanical switch or Hall sensor, but pressure fluctuations or decreases as the user tries to disengage the cable can provide early warning of the cable’s removal, increasing the time available to perform a graceful shutdown.

Some implementations of detection module 310 implement power cable removal detection using one or more capacitive sensors implemented in capacitive touch surfaces, arranged on the cable so that a user touches one or more of the capacitive touch surfaces on the cable when the user grasps the cable to remove it. One embodiment includes capacitive touch surfaces on two sides of the cable to minimize the risk of false triggering.

In event handling module 320 within a head-worn device, a cable removal detection signal event hits a microcontroller configured to detect cable removal. In another implementation of module 320, a cable removal detection signal is routed to a power management circuit directly, bypassing the microcontroller). In response, the microcontroller signals the power management circuit to initiate a graceful shutdown of all the power rails on the head-worn device. In some implementations of module 320, a power bank or battery temporarily supplies power for the scenario when power through the cable connector is shut off immediately, before the graceful shutdown completes. Another implementation of module 320 performs an additional task upon cable removal detection.

In an implementation of module 320 within a compute/battery device, a cable removal detection signal event hits a microcontroller or system-on-chip (SoC) configured to detect cable removal. In another implementation of module 320, a cable removal detection signal is routed to a power management circuit directly, bypassing the microcontroller or SoC). In response, the microcontroller or SoC signals the power management circuit to initiate a graceful shutdown of all the power rails on the head-worn device. Another implementation of module 320 performs an additional task upon cable removal detection.

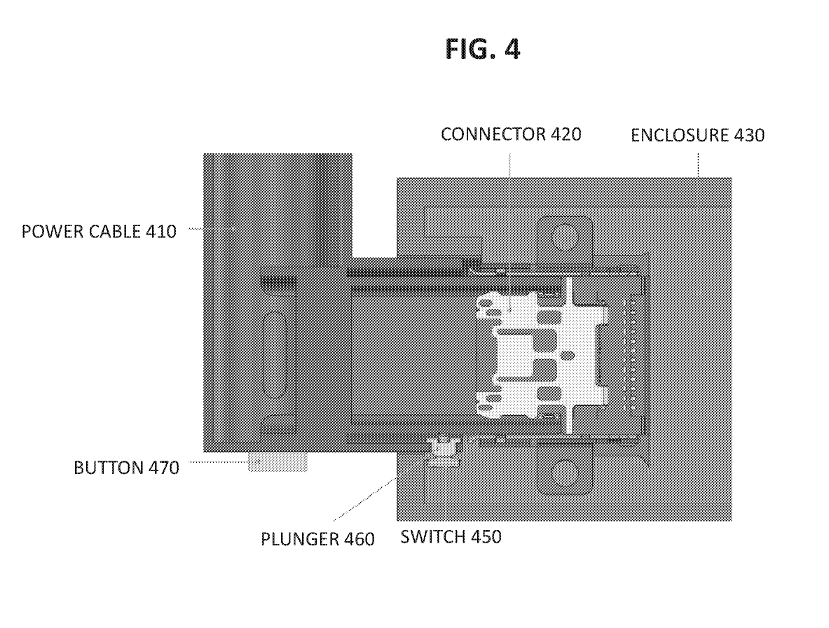

FIG. 4 depicts an example mechanical configuration for power cable removal detection, in accordance with an illustrative embodiment.

In particular, FIG. 4 depicts a mechanical switch option for power cable removal detection. As depicted, power cable 410 is plugged into connector 420 within enclosure 430. Spring-loaded plunger 460 (actuated by button 470 or self-actuated) presses on mechanical switch 450 when power cable 410 is engaged. Mechanical switch 450 is unpressed, or released, when power cable 410 is removed. One implementation includes button 470 mechanically coupled to plunger 460. When a user presses button 470, plunger 460 disengages and mechanical switch 450 is unpressed. In another implementation, plunger 460 is designed to disengage as a user pulls power cable 410 out, releasing mechanical switch 450.

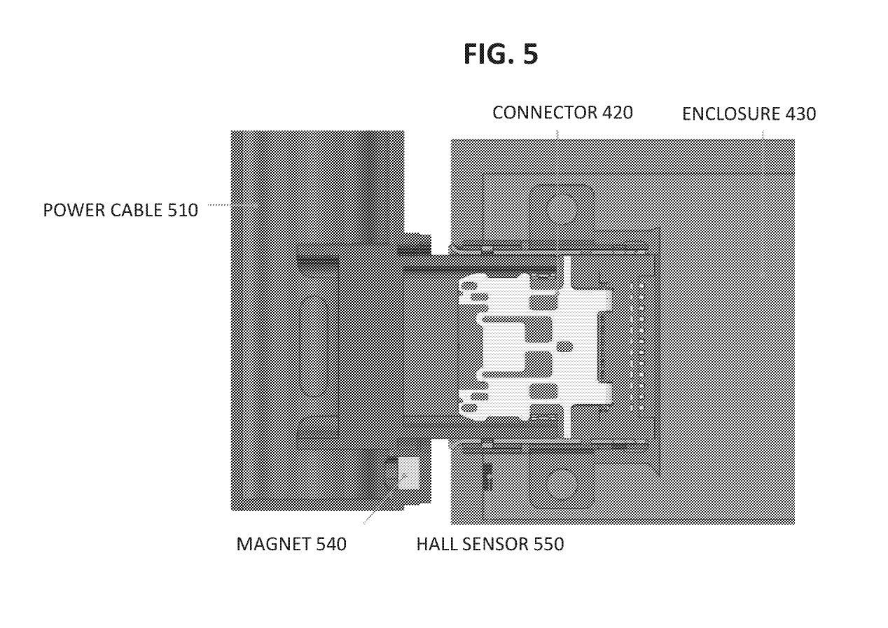

FIG. 5 depicts another example mechanical configuration for power cable removal detection, in accordance with an illustrative embodiment. Connector 420 and enclosure 430 are the same as connector 420 and enclosure 430 in FIG. 4.

In particular, FIG. 5 depicts a Hall sensor option for power cable removal detection. As depicted, power cable 510 is plugged into connector 420 within enclosure 430. Power cable 510 includes magnet 540. Enclosure 430 includes Hall sensor 550. Hall sensor 550 detects magnetic strength from magnet 540 in cable 510, and the strength drops as cable 510 is removed.

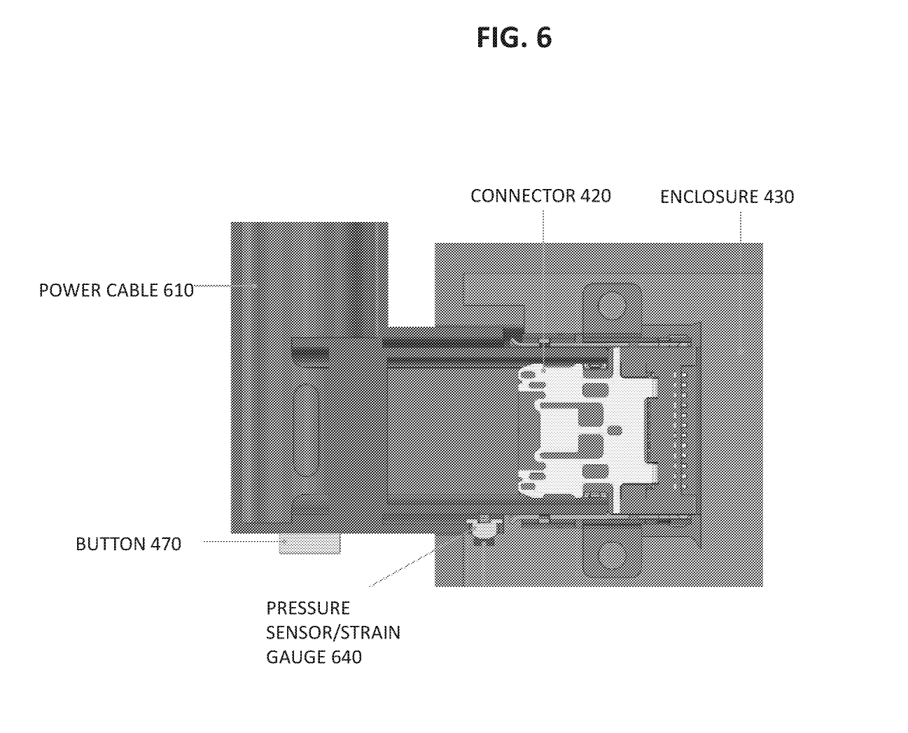

FIG. 6 depicts another example mechanical configuration for power cable removal detection. in accordance with an illustrative embodiment. Connector 420, enclosure 430, and button 470 are the same as connector 420, enclosure 430, and button 470 in FIG. 4.

In particular, FIG. 6 depicts a pressure sensor or strain gauge option for power cable removal detection. As depicted, power cable 610 is plugged into connector 420 within enclosure 430. A spring-loaded plunger (actuated by button 470 or self-actuated) applies pressure on pressure sensor or strain gauge 640 when cable 610 is engaged. The pressure is removed when cable 610 is removed. One implementation includes button 470 mechanically coupled to the plunger. When a user presses button 470, the plunger disengages and the pressure is removed from pressure sensor or strain gauge 640. In another implementation, the plunger is designed to disengage as a user pull cable 610 out, removing pressure from pressure sensor or strain gauge 640. Cable removal detection using a pressure sensor or strain gauge can take longer than using a mechanical switch or Hall sensor, but pressure fluctuations or decreases as the user tries to disengage the cable can provide early warning of the cable’s removal, increasing the time available to perform a graceful shutdown.

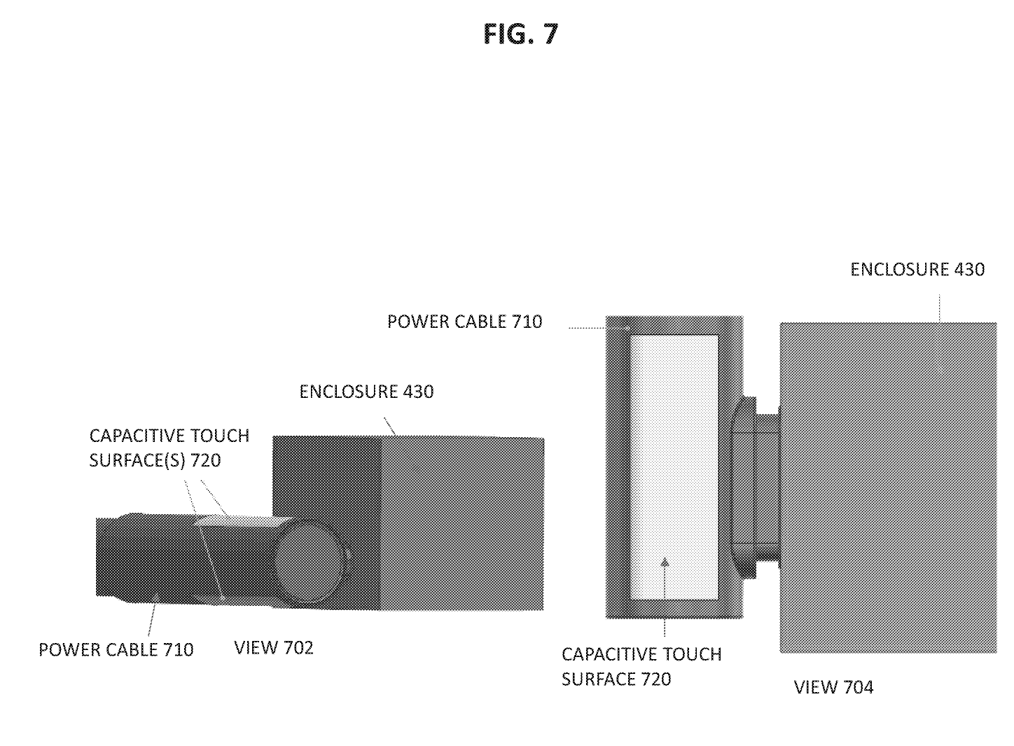

FIG. 7 depicts another example mechanical configuration for power cable removal detection. in accordance with an illustrative embodiment. Enclosure 430 is the same as enclosure 430 in FIG. 4.

In particular, FIG. 7 depicts views 702 and 704 of a capacitive sensor option for power cable removal detection. Power cable 710 includes one or more capacitive sensors implemented in capacitive touch surfaces 720, arranged on cable 710 so that a user touches one or more of capacitive touch surfaces 720 on cable 710 when the user grasps cable 710 to remove it. One implementation, depicted in view 702, includes capacitive touch surfaces 720 on two sides of cable 710 to minimize the risk of false triggering.

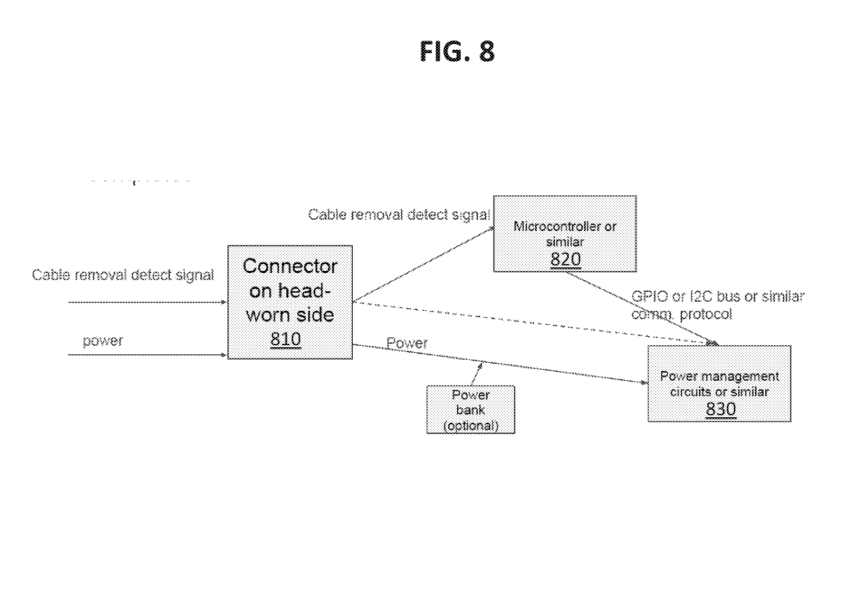

FIG. 8 depicts example events in power cable removal detection. in accordance with an illustrative embodiment.

In particular, FIG. 8 depicts a chain of events post detection at a head-worn device disconnecting from a compute/battery device. In an implementation within a head-worn device, in block 810 a cable removal detection signal event is detected at a connector on the head-worn device and hits a microcontroller configured to detect cable removal. In response, in block 820 the microcontroller signals the power management circuit to initiate (in block 830) a graceful shutdown of all the power rails on the head-worn device. In some implementations, a power bank or battery temporarily supplies power for the scenario when power through the cable connector is shut off immediately, before the graceful shutdown completes. Another implementation performs an additional task upon cable removal detection.

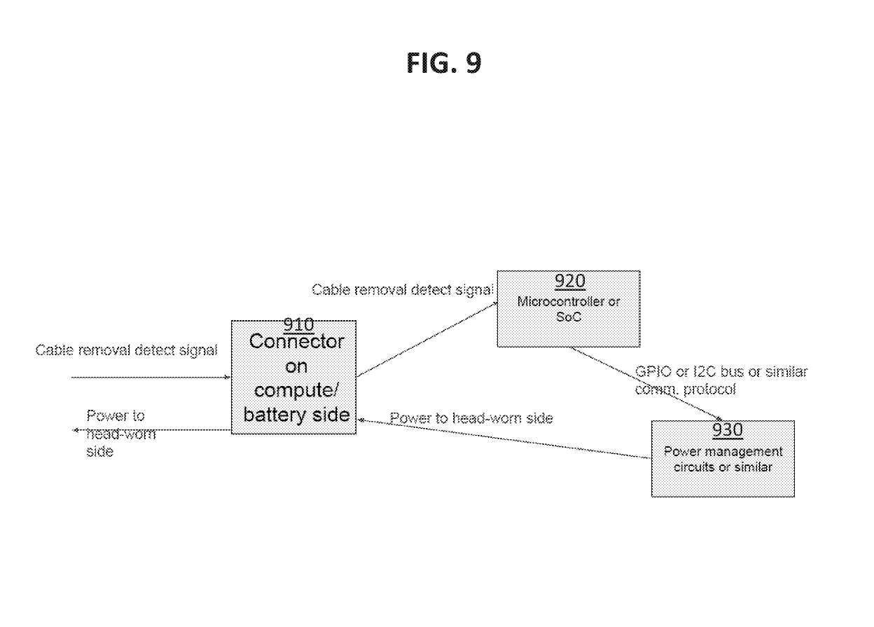

FIG. 9 depicts example events in power cable removal detection. in accordance with an illustrative embodiment.

In particular, FIG. 9 depicts a chain of events post detection at compute/battery device disconnecting from a head-worn device. In an implementation within a compute/battery device, a cable removal detection signal event is detected (block 910) at a connector at the compute/battery device and (in block 920) hits a microcontroller or system-on-chip (SoC) configured to detect cable removal. In response, the microcontroller or SoC signals the power management circuit to (in block 930) initiate a graceful shutdown of all the power rails on the head-worn device. Another implementation performs an additional task upon cable removal detection.

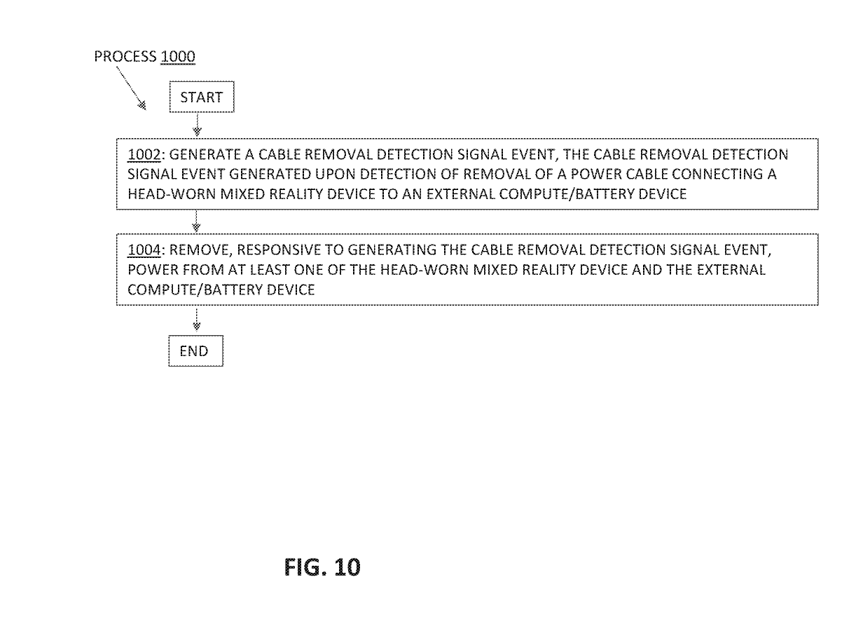

FIG. 10 depicts a flowchart of an example process for power cable removal detection, in accordance with an illustrative embodiment. Process 1000 can be implemented in application 222 in FIG. 2.

At block 1002, the process generates a cable removal detection signal event, the cable removal detection signal event generated upon detection of removal of a power cable connecting a head-worn mixed reality device to an external compute/battery device. At block 1004, the process removes, responsive to generating the cable removal detection signal event, power from at least one of the head-worn mixed reality device and the external compute/battery device. Then the process ends.

Many of the above-described features and applications may be implemented as software processes that are specified as a set of instructions recorded on a computer-readable storage medium (alternatively referred to as computer-readable media, machine-readable media, or machine-readable storage media). When these instructions are executed by one or more processing unit(s) (e.g., one or more processors, cores of processors, or other processing units), they cause the processing unit(s) to perform the actions indicated in the instructions. Examples of computer-readable media include, but are not limited to, RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, ultra-density optical discs, any other optical or magnetic media, and floppy disks. In one or more embodiments, the computer-readable media does not include carrier waves and electronic signals passing wirelessly or over wired connections, or any other ephemeral signals. For example, the computer-readable media may be entirely restricted to tangible, physical objects that store information in a form that is readable by a computer. In one or more embodiments, the computer-readable media is non-transitory computer-readable media, computer-readable storage media, or non-transitory computer-readable storage media.

In one or more embodiments, a computer program product (also known as a program, software, software application, script, or code) can be written in any form of programming language, including compiled or interpreted languages, declarative or procedural languages, and it can be deployed in any form, including as a standalone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

While the above discussion primarily refers to microprocessor or multi-core processors that execute software, one or more embodiments are performed by one or more integrated circuits, such as application specific integrated circuits (ASICs) or field programmable gate arrays (FPGAs). In one or more embodiments, such integrated circuits execute instructions that are stored on the circuit itself.

The accompanying appendix, which is included to provide further understanding of the subject technology and is incorporated in and constitutes a part of this specification, illustrates aspects of the subject technology and together with the description serves to explain the principles of the subject technology.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Those of skill in the art would appreciate that the various illustrative blocks, modules, elements, components, methods, and algorithms described herein may be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way), all without departing from the scope of the subject technology.

It is understood that any specific order or hierarchy of blocks in the processes disclosed is an illustration of example approaches. Based upon implementation preferences, it is understood that the specific order or hierarchy of blocks in the processes may be rearranged, or that not all illustrated blocks be performed. Any of the blocks may be performed simultaneously. In one or more embodiments, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

The subject technology is illustrated, for example, according to various aspects described above. The present disclosure is provided to enable any person skilled in the art to practice the various aspects described herein. The disclosure provides various examples of the subject technology, and the subject technology is not limited to these examples. Various modifications to these aspects will be readily apparent to those skilled in the art, and the generic principles defined herein may be applied to other aspects.

A reference to an element in the singular is not intended to mean “one and only one” unless specifically stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the disclosure.

To the extent that the terms “include,” “have,” or the like is used in the description or the claims or clauses, such term is intended to be inclusive in a manner similar to the term “comprise” as “comprise” is interpreted when employed as a transitional word in a claim.

The word “exemplary” is used herein to mean “serving as an example, instance, or illustration.” Any embodiment described herein as “exemplary” is not necessarily to be construed as preferred or advantageous over other embodiments. In one aspect, various alternative configurations and operations described herein may be considered to be at least equivalent.

As used herein, the phrase “at least one of” preceding a series of items, with the terms “and” or “or” to separate any of the items, modifies the list as a whole, rather than each member of the list (i.e., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

A phrase such as an “aspect” does not imply that such aspect is essential to the subject technology or that such aspect applies to all configurations of the subject technology. A disclosure relating to an aspect may apply to all configurations, or one or more configurations. An aspect may provide one or more examples. A phrase such as an aspect may refer to one or more aspects and vice versa. A phrase such as an “embodiment” does not imply that such embodiment is essential to the subject technology or that such embodiment applies to all configurations of the subject technology. A disclosure relating to an embodiment may apply to all embodiments, or one or more embodiments. An embodiment may provide one or more examples. A phrase such as an embodiment may refer to one or more embodiments and vice versa. A phrase such as a “configuration” does not imply that such configuration is essential to the subject technology or that such configuration applies to all configurations of the subject technology. A disclosure relating to a configuration may apply to all configurations, or one or more configurations. A configuration may provide one or more examples. A phrase such as a configuration may refer to one or more configurations and vice versa.

In one aspect, unless otherwise stated, all measurements, values, ratings, positions, magnitudes, sizes, and other specifications that are set forth in this specification, including in the claims or clauses that follow, are approximate, not exact. In one aspect, they are intended to have a reasonable range that is consistent with the functions to which they relate and with what is customary in the art to which they pertain. It is understood that some or all steps, operations, or processes may be performed automatically, without the intervention of a user.

Method claims or clauses may be provided to present elements of the various steps, operations, or processes in a sample order, and are not meant to be limited to the specific order or hierarchy presented.

In one aspect, a method may be an operation, an instruction, or a function and vice versa. In one aspect, a claim may be amended to include some or all of the words (e.g., instructions, operations, functions, or components) recited in other one or more claims, one or more words, one or more sentences, one or more phrases, one or more paragraphs, and/or one or more claims.

All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. No claim element is to be construed under the provisions of 35 U.S.C. §112, sixth paragraph, unless the element is expressly recited using the phrase “means for” or, in the case of a method claim, the element is recited using the phrase “step for.”

The Title, Background, and Brief Description of the Drawings of the disclosure are hereby incorporated into the disclosure and are provided as illustrative examples of the disclosure, not as restrictive descriptions. It is submitted with the understanding that they will not be used to limit the scope or meaning of the claims. In addition, in the Detailed Description, it can be seen that the description provides illustrative examples, and the various features are grouped together in various embodiments for the purpose of streamlining the disclosure. This method of disclosure is not to be interpreted as reflecting an intention that the included subject matter requires more features than are expressly recited in any claim. Rather, as the claims reflect, inventive subject matter lies in less than all features of a single disclosed configuration or operation. The claims are hereby incorporated into the Detailed Description, with each claim standing on its own to represent separately patentable subject matter.

The claims or clauses are not intended to be limited to the aspects described herein but are to be accorded the full scope consistent with the language of the claims and to encompass all legal equivalents. Notwithstanding, none of the claims are intended to embrace subject matter that fails to satisfy the requirement of 35 U.S.C. § 101, 102, or 103, nor should they be interpreted in such a way.

Embodiments consistent with the present disclosure may be combined with any combination of features or aspects of embodiments described herein.

1. A computer-implemented method comprising:
generating a cable removal detection signal event, the cable removal detection signal event generated upon detection of removal of a power cable connecting a head-worn mixed reality device to an external compute/battery device; and
removing, responsive to generating the cable removal detection signal event, power from at least one of the head-worn mixed reality device and the external compute/battery device.

2. The computer-implemented method of claim 1, wherein the cable removal detection signal event is generated by release of pressure on a mechanical switch when the power cable is removed.

3. The computer-implemented method of claim 2, wherein the mechanical switch comprises a spring-loaded plunger configured to disengage as the power cable is removed.

4. The computer-implemented method of claim 2, wherein the mechanical switch comprises a button mechanically coupled to a spring-loaded plunger, the spring-loaded plunger configured to disengage when the button is pressed.

5. The computer-implemented method of claim 1, wherein the cable removal detection signal event is generated by a Hall effect sensor detecting a reduction in magnetic strength from a magnet in the power cable when the power cable is removed.

6. The computer-implemented method of claim 1, wherein the cable removal detection signal event is generated by release of pressure on a pressure sensor when the power cable is removed.

7. The computer-implemented method of claim 1, wherein the cable removal detection signal event is generated by release of pressure on a strain gauge when the power cable is removed.

8. The computer-implemented method of claim 1, wherein the cable removal detection signal event is generated by detecting touch on at least one capacitive sensor implemented on a capacitive touch surface of the power cable, the at least one capacitive sensor configured to detect touch during power cable removal.

9. A non-transitory computer-readable medium storing a program, which when executed by a computer, configures the computer to:
generate a cable removal detection signal event, the cable removal detection signal event generated upon detection of removal of a power cable connecting a head-worn mixed reality device to an external compute/battery device; and
remove, responsive to generating the cable removal detection signal event, power from at least one of the head-worn mixed reality device and the external compute/battery device.

10. The non-transitory computer-readable medium of claim 9, wherein the cable removal detection signal event is generated by release of pressure on a mechanical switch when the power cable is removed.

11. The non-transitory computer-readable medium of claim 10, wherein the mechanical switch comprises a spring-loaded plunger configured to disengage as the power cable is removed.

12. The non-transitory computer-readable medium of claim 10, wherein the mechanical switch comprises a button mechanically coupled to a spring-loaded plunger, the spring-loaded plunger configured to disengage when the button is pressed.

13. The non-transitory computer-readable medium of claim 9, wherein the cable removal detection signal event is generated by a Hall effect sensor detecting a reduction in magnetic strength from a magnet in the power cable when the power cable is removed.

14. The non-transitory computer-readable medium of claim 9, wherein the cable removal detection signal event is generated by release of pressure on a pressure sensor when the power cable is removed.

15. The non-transitory computer-readable medium of claim 9, wherein the cable removal detection signal event is generated by release of pressure on a strain gauge when the power cable is removed.

16. The non-transitory computer-readable medium of claim 9, wherein the cable removal detection signal event is generated by detecting touch on at least one capacitive sensor implemented on a capacitive touch surface of the power cable, the at least one capacitive sensor configured to detect touch during power cable removal.

17. A system comprising:
a processor; and
a non-transitory computer readable medium storing a set of instructions, which when executed by the processor, configure the system to:
generate a cable removal detection signal event, the cable removal detection signal event generated upon detection of removal of a power cable connecting a head-worn mixed reality device to an external compute/battery device; and
remove, responsive to generating the cable removal detection signal event, power from at least one of the head-worn mixed reality device and the external compute/battery device.

18. The system of claim 17, wherein the cable removal detection signal event is generated by release of pressure on a mechanical switch when the power cable is removed.

19. The system of claim 18, wherein the mechanical switch comprises a spring-loaded plunger configured to disengage as the power cable is removed.

20. The system of claim 18, wherein the mechanical switch comprises a button mechanically coupled to a spring-loaded plunger, the spring-loaded plunger configured to disengage when the button is pressed.
